(19) United States
(12) Patent Application Publication
(10) Pub. No.: US 2016/0216152 A1
(43) Pub. Date: Jul. 28, 2016

(54) VIBRATIONAL SENSOR DEVICE AND METHOD FOR DETECTING AN ENERGIZED TRANSFORMER

(71) Applicant: VIRGINIA TRANSFORMER CORPORATION, Roanoke, VA (US)

(72) Inventor: Prabhat JAIN, Roanoke, VA (US)

(73) Assignee: VIRGINIA TRANSFORMER CORPORATION, Roanoke, VA (US)

(21) Appl. No.: 14/606,707

(22) Filed: Jan. 27, 2015

(51) Int. Cl. G01H 11/02; G01R 31/02

(52) U.S. Cl. CPC G01H 11/02; G01R 31/027

(57) ABSTRACT

A vibrational sensor device and method for detecting an energized transformer is disclosed. The device may sense when a liquid-filled transformer is excited either fully or partially. The device may sense when a liquid-filled transformer is operating with or without a load current on a secondary winding of the transformer. The device may annunciate a full excitation state, a partial excitation state, a no excitation state, an OK power supply state and a low battery state. The device may detect magneto restriction vibrations at twice a line frequency such as at 120 Hz for a 60 Hz transformer. The device may be installed on a new or a retro-fit liquid-filled transformer.

### BACKGROUND

The core of a liquid-filled transformer often produces vibrations due to the magneto restriction phenomenon at twice the frequency of the alternating current or AC voltage. For a 60 Hz power supply, the vibration frequency is 120 Hz. This vibration is transmitted to the tank walls of the liquid-filled transformer through the liquid surrounding the core. This vibration can be sensed by a vibrational sensor device which is mounted on the outside of the wall of the liquid-filled transformer and capable of picking-up this range of frequency. Detection and alerts related to vibrations, however, are not presently available.

### SUMMARY

In one exemplary embodiment, a vibrational sensor device may be described. The vibrational sensor device may include an enclosure having a front surface and a back surface, the enclosure protecting the vibrational sensor device, a mounting plate having a front surface and a back surface. The back surface of the mounting plate may be coupled to an outside portion of a liquid-filled transformer and the front surface of the mounting plate may be coupled to the back surface of the enclosure and any number of annunciator and relay contacts may be disposed inside of the enclosure. The annunciator and relay contacts can be energized by a vibrational sensor disposed inside of the enclosure, and the annunciator and relay contacts can annunciate a full excitation state, a partial excitation state, a no excitation state and a power supply OK state. The vibrational sensor device may also include any number of contact output lights disposed on the front surface of the enclosure. The contact output lights can be activated by the annunciator and relay contacts being energized by the vibrational sensor, and the contact output lights may include a full excitation light, a partial excitation light, a no excitation light, a power supply OK light, a low battery light and a power supply providing electrical power to the vibration sensor.

In some exemplary embodiments, a vibrational sensor device may be utilized to sense when a liquid-filled transformer is excited, either fully or partially, and can provide quick and critical information for safety, troubleshooting and maintenance. Additionally, a vibrational sensor device may sense when a liquid-filled transformer is operating with or without a load current on a secondary winding of the transformer and may also provide quick and critical information for safety, troubleshooting and maintenance. Further, a vibrational sensor device can have visual annunciators that indicate full excitation, partial excitation, no excitation, and a low battery (if present) to provide quick visual operational states for the transformer for safety, troubleshooting and maintenance. In further embodiments, a vibrational sensor device may have contact relay annunciators that indicate full excitation, partial excitation, no excitation, and a low battery (if present) may provide quick remote operational states for the transformer for safety, troubleshooting and maintenance are also present.

In still further exemplary embodiments, a vibrational sensor device can have an internal low-voltage battery option that may provide a low-cost or simplified installation without electrical conduits. Additionally, a vibrational sensor device may further have a sensor plate which may be mounted magnetically, bolted, epoxy, glued or welded provides multiple mounting options to a customer.

In another exemplary embodiment, a method for detecting an energized transformer is described. The method steps may include obtaining a vibrational sensor device, coupling the vibrational sensor device to an outside portion of the energized transformer, activating the vibrational sensor device with a plurality of energized transformer states and having the vibrational sensor device detect magneto restriction vibrations from the energized transformer.

### BRIEF DESCRIPTION OF THE DRAWINGS

Advantages of embodiments of the present invention will be apparent from the following detailed description of the exemplary embodiments thereof, which description should be considered in conjunction with the accompanying drawings in which like numerals indicate like elements, in which:

FIG. 1 is an exemplary diagram showing a vibrational sensor device mounted to an outside portion of a liquid-filled transformer.

FIG. 2 is an exemplary electrical diagram of a vibrational sensor device.

FIG. 3 is an exemplary diagram showing a flowchart of a method for detecting an energized transformer.

### DETAILED DESCRIPTION

Aspects of the present invention are disclosed in the following description and related figures directed to specific embodiments of the present invention. Those skilled in the art will recognize that alternate embodiments may be devised without departing from the spirit or the scope of the claims. Additionally, well-known elements of exemplary embodiments of the present invention will not be described in detail or will be omitted so as not to obscure the relevant details of the present invention.

As used herein, the word “exemplary” means “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the present invention”, “embodiments” or “present invention” do not require that all embodiments of the present invention include the discussed feature, advantage, or mode of operation.

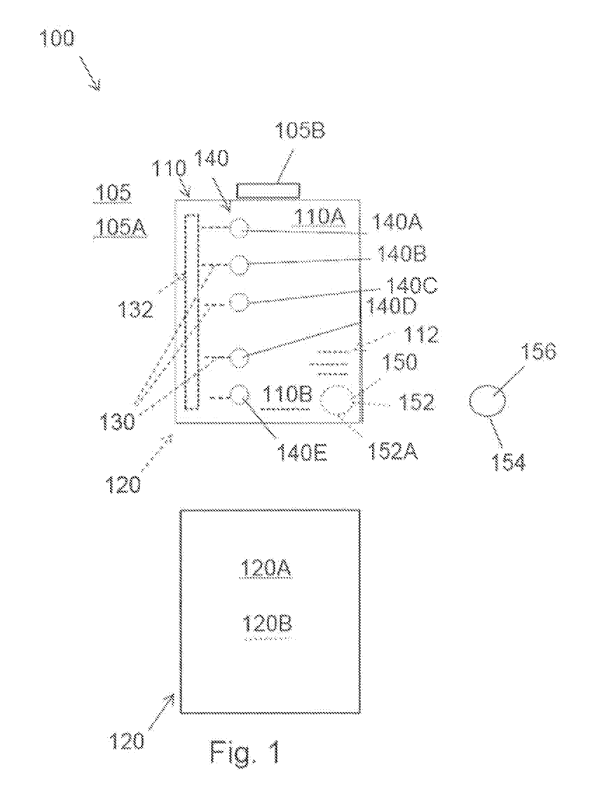

FIG. 1 is an exemplary diagram showing a vibrational sensor device 100 that may be mounted to an outside portion 105A of a liquid-filled transformer 105.

The vibrational sensor device 100 may include an enclosure 110, a mounting plate 120, any number of annunciator and relay contacts 130, any number of contact output lights 140 and a power supply 150.

Still referring to exemplary FIG. 1, the enclosure 110 may protect the vibrational sensor device 100. The enclosure 110 may include a front surface 110A and a back surface 110B. The mounting plate 120 may have a front surface 120A and a back surface 120B. The back surface 120B of the mounting plate 120 may be coupled to the outside portion 105A of a liquid-filled transformer 105, and the like. The front surface 120A of the mounting plate 120 may be coupled to the back surface 110B of the enclosure 110 with any number of fasteners 112. Such fasteners may include, but are not limited to, magnetics and magnets, bolts, screws, epoxy, or glue, either alone or in combination with any other element. The annunciator and relay contacts 130 may be disposed inside of the enclosure 110 and can be energized by a vibration sensor 132 disposed inside of the enclosure 110. The annunciator and relay contacts 130, depending on the power level of the vibration sensor device 100, may annunciate a full excitation state, a partial excitation state, a no excitation state, a power supply OK state and a low battery state if a battery is present. The vibration sensor 132 may detect magneto restriction vibrations at approximately 120 Hz (twice a line frequency) for a 60 Hz power supply, or the like, within the liquid-filled transformer 105. It may further be appreciated by those having ordinary skill in the art that the vibration sensor 132 may be utilized with power supplies having any desired operating frequency and that 60 Hz is used merely as an example. The back surface 110B of the enclosure 110 may also be coupled directly to the outside portion 105A of a liquid-filled transformer 105 without the mounting plate 120. The contact output lights 140 may be disposed on a front surface 110A inside of the enclosure 110. The contact output lights 140 may be activated by the annunciator and relay contacts 130 being energized by the vibration sensor 132. The contact output lights 140 may include a full excitation light 140A, a partial excitation light 140B, a no excitation light 140C, a power supply OK light 140D and a low battery light 140E, and the like. The power supply 150 may provide electrical power to the vibration sensor 132. The power supply 150 may be a battery 152 such as an internal low-voltage battery 152A or an optional external power supply 154 such as an electrical outlet 156 or the like. The vibrational sensor device 100 may sense when the energized transformer 105 is operating with or without a load current on a secondary winding 105B of the energized transformer.

Further, and still referring to exemplary FIG. 1, the vibrational sensor device 100 may be coupled directly to the outside 105A of a liquid-filled transformer 105 on a mounting plate 120. The vibrational sensor device 100 may be powered by an internal battery 152 or by an external power source 154. The vibrational sensor device 100 may detect magneto restriction vibrations at approximately 120 Hz which is approximately twice a line frequency, in this exemplary embodiment.

In further exemplary embodiments, when the power level of the vibrational sensor device 100 is below a first preset threshold, then the “No Excitation” annunciator and relay contact may be energized to activate a no excitation light. When the power level of the vibrational sensor device 100 is above the first preset threshold and below a second preset threshold, then the “Partial Excitation” annunciator and relay contact may be energized to activate a partial excitation light. When the power level of the vibrational sensor device is above the second preset threshold, then the “Full Excitation” annunciator and relay contact may be energized to activate a full excitation light. While the power supply or battery voltage level is within operational range, the “Power Supply” annunciator and relay contact may be energized to activate a power supply OK light. If a battery is present and its voltage is low, then the “Low Battery” annunciator and relay contact may be energized to activate a low battery excitation light.

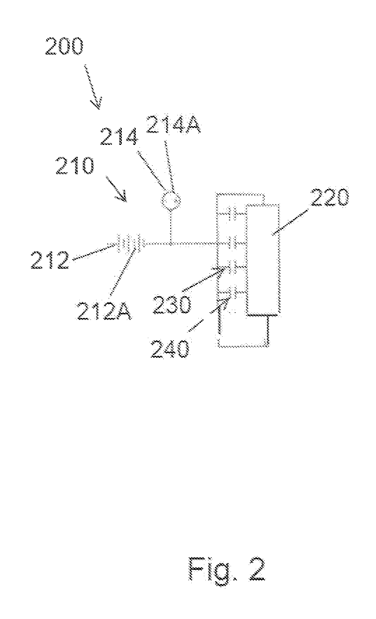

FIG. 2 is an exemplary electrical diagram of a vibrational sensor device 200.

In exemplary FIG. 2, a vibrational sensor device 200 may include a power supply 210, a vibration sensor 220, any number of annunciator and relay contacts 230 and any number of contact output lights 240.

The power supply 210 may be a battery 212, such as an internal low-voltage battery 212A and the like, or an external power source 214 such as an electrical outlet 214A. The vibration sensor 220 may be in electrical communication with the power supply 210. The power supply 210 may provide electrical power to the vibration sensor 220 to allow the vibration sensor 220 to detect magneto restriction vibrations at approximately 120 Hz which is approximately twice a line frequency in this exemplary embodiment. The annunciator and relay contacts 230 may be in electrical communication with the vibration sensor 220 and may be energized by the vibration sensor 220. The contact output lights 240 may be in electrical communication with the annunciator and relay contacts 230 and may be activated by the annunciator and relay contacts 230.

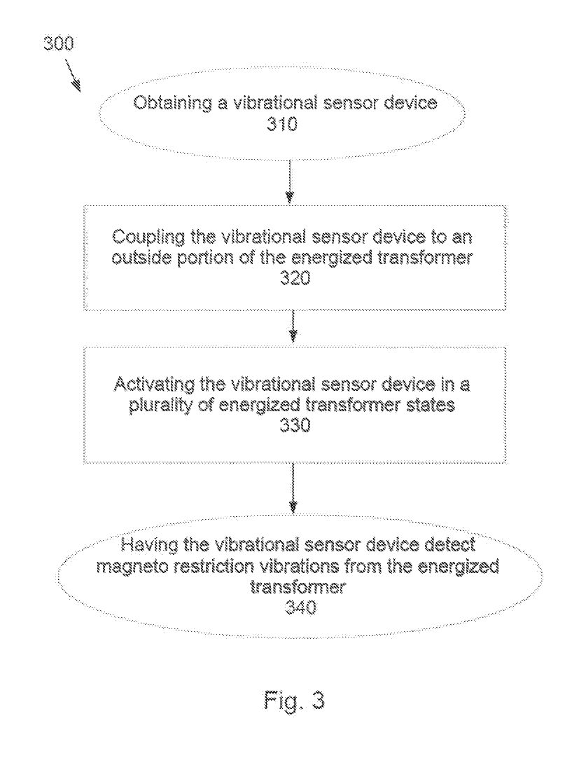

FIG. 3 is an exemplary diagram showing a flowchart of a method for detecting an energized transformer 300.

The method for detecting an energized transformer 300 may include the steps of obtaining a vibrational sensor device 310, coupling the vibrational sensor device to an outside portion of the energized transformer 320, activating the vibrational sensor device in a plurality of energized transformer states 330 and having the vibrational sensor device detect magneto restriction vibrations from the energized transformer 340.

The obtaining step 310 may include exemplary embodiments where the vibrational sensor device is installed on a new transformer or retro-fitted to an existing transformer. During the coupling step 320, the vibrational sensor device being coupled to a mounting plate by any number of fasteners. The fasteners can include, but are not limited to, magnetic fasteners, bolts, screws, epoxy, glue, and the like. In the activating step 330, the annunciator and relay contacts may annunciate a full excitation state, a partial excitation state, a no excitation state, an OK power supply state and a low battery state. Such states may be annunciated when the appropriate conditions are present. For example, a low battery state may be annunciated when a battery is being utilized and its power is running low or near exhaustion. The having step 340 may include the vibrational sensor device detects magneto restriction vibrations at approximately twice a line frequency, wherein the vibrational sensor device detects magneto restriction vibrations at approximately 120 Hz for a 60 Hz transformer. The detecting involved with step 340 may include having the vibrational sensor device sense when the energized transformer is operating with or without a load current on a secondary winding of the energized transformer.

In these exemplary embodiments a variety of benefits associated with a vibrational sensor device and method for detecting an energized transformer may be realized. A vibrational sensor may provide visual, audio, or other indication of when a liquid-filled transformer is excited, either fully or partially, and may also provide quick and critical information for safety, troubleshooting and maintenance. In further examples, a vibrational sensor may provide information as to when a liquid-filled transformer is operating with or without a load current on a secondary winding of the transformer and also provide quick and critical information for safety, troubleshooting and maintenance. Visual annunciators may indicate full excitation, partial excitation, no excitation, and low battery (if present) can provide quick visual operational states for the transformer for safety, troubleshooting and maintenance and can provide easy to read or interpret information to a user. Contact relay annunciators that indicate full excitation, partial excitation, no excitation, and a low battery (if present) may provide quick remote operational states for the transformer for safety, troubleshooting and maintenance for users or operators. An internal low-voltage battery option, in some exemplary embodiments, can further allow for a low-cost installation without the use of electrical conduits. A sensor plate may also be utilized and may be mounted magnetically, bolted, epoxy, glued or welded to provide multiple mounting options to a user or customer.

The foregoing description and accompanying figures illustrate the principles, embodiments and modes of operation of the present invention. However, the present invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments may be made by those skilled in the art without departing from the scope of the present invention as defined by the following claims.

What is claimed is:

1. A vibrational sensor device, comprising:
an enclosure having a front surface and a back surface, the enclosure protecting a vibrational sensor device;
a mounting plate having a front surface and a back surface, the back surface of the mounting plate coupled to an outside portion of a liquid-filled transformer and the front surface of the mounting plate coupled to the back surface of the enclosure;
a plurality of annunciator and relay contacts disposed inside of the enclosure, the annunciator and relay contacts energized by a vibration sensor disposed inside of the enclosure, wherein the annunciator and relay contacts annunciate a full excitation state of the vibration sensor, a partial excitation state of the vibration sensor, a no excitation state of the vibration sensor and a power supply OK state;
a plurality of contact output lights disposed on the front surface of the enclosure, the contact output lights activated by the annunciator and relay contacts being energized by the vibration sensor, wherein the contact output lights include a full excitation light, a partial excitation light, a no excitation light, a power supply OK light and a low battery light; and
a power supply providing electrical power to the vibration sensor.

2. The vibrational sensor device according to claim 1, wherein the back surface of the mounting plate is coupled to the outside portion of the liquid-filled transformer with a plurality of fasteners.

3. The vibrational sensor device according to claim 1, wherein the back surface of the enclosure is coupled directly to the outside portion of the liquid-filled transformer without the mounting plate.

4. The vibrational sensor device according to claim 1, wherein the vibration sensor detects magneto restriction vibrations at twice a line frequency.

5. The vibrational sensor device according to claim 4, wherein the magneto restriction vibrations are about 120 Hz for a 60 Hz power supply.

6. The vibrational sensor device according to claim 1, wherein the annunciator and relay contacts annunciate a low battery state.

7. The vibrational sensor device according to claim 1, wherein the power supply is an internal low-voltage battery.

8. The vibrational sensor device according to claim 1, wherein the power supply is an external power supply.

9. The vibrational sensor device according to claim 1, wherein the vibrational sensor device is installed on a retro-fit liquid-filled transformer.

10. A method for detecting an energized transformer, comprising:
coupling a vibration sensor device to an outside portion of an energized transformer;
activating the vibration sensor device with a plurality of energized transformer states; and
detecting, by the vibration sensor, magneto restriction vibrations from the energized transformer.

11. The method for detecting an energized transformer according to claim 10, further comprising retro-fitting the vibration sensor on the transformer.

12. The method for detecting an energized transformer according to claim 10, further comprising coupling the vibration sensor device to a mounting plate.

13. The method for detecting an energized transformer according to claim 12, further comprising coupling a back surface to the mounting plate to the outside portion of the liquid-filled transformer with one or more fasteners.

14. The method for detecting an energized transformer according to claim 13, wherein the one or more fasteners are at least one of magnetic fasteners, bolts, screws, epoxy, and glue.

15. The method for detecting an energized transformer according to claim 10, further comprising annunciating a full excitation state of the vibration sensor, a partial excitation state of the vibration sensor, a no excitation state of the vibration sensor, an OK power supply state of the vibration sensor and a low battery state.

16. The method for detecting an energized transformer according to claim 10, wherein the vibration sensor device detects magneto restriction vibrations at twice a line frequency.

17. The method for detecting an energized transformer according to claim 16, wherein the vibrational sensor device detects magneto restriction vibrations at 120 Hz for a 60 Hz transformer.

18. The method for detecting an energized transformer according to claim 10, further comprising sensing, by the vibration sensor device, when the energized transformer is operating with or without a load current on a secondary winding of the energized transformer.
